(19) United States
(12) Patent Application Publication
(10) Pub. No.: US 2024/0194840 A1
(43) Pub. Date: Jun. 13, 2024

(54) DISPLAY MODULE INCLUDING OPTICAL FILM

(71) Applicant: Samsung Electronics Co., Ltd., Suwon-si (KR)

(72) Inventors: Eunhye KIM, Suwon-si (KR); Mingyu LEE, Suwon-si (KR); Yoonsuk LEE, Suwon-si (KR); Seungryong HAN, Suwon-si (KR)

(73) Assignee: Samsung Electronics Co., Ltd., Suwon-si (KR)

(21) Appl. No.: 18/410,670

(22) Filed: Jan. 11, 2024

Related U.S. Application Data
(63) Continuation of application No. PCT/KR2023/017509, filed on Nov. 3, 2023.

(30) Foreign Application Priority Data
Dec. 13, 2022 (KR) 10-2022-0173650

(51) Int. Cl. H01L 33/58; H01L 25/16

(52) U.S. Cl. CPC H01L 33/58; H01L 25/167

(57) ABSTRACT

A display module includes a display substrate, a plurality of light emitting diodes (LEDs) provided on the substrate, an adhesive layer provided on a first surface of the substrate on which the plurality of LEDs are provided, and an optical film connected to the substrate by the adhesive layer and configured to increase luminous intensity by scattering light emitted by the plurality of LEDs.

### CROSS REFERENCE TO RELATED APPLICATIONS

This application is a continuation of International Application No. PCT/KR2023/017509, filed on Nov. 3, 2023, in the Korean Intellectual Property Receiving Office, which is based on and claims priority to Korean Patent Application No. 10-2022-0173650, filed on Dec. 13, 2022, in the Korean Intellectual Property Office, the disclosures of which are incorporated herein by reference in their entireties.

### BACKGROUND

### 1. Field

The disclosure relates to a display module including an optical film.

### 2. Description of the Related Art

A light emitting diode (LED) is widely used as a light source for a lighting device as well as a light source of various electronic devices like various electronic goods such as a television, a mobile phone, a personal computer (PC), a notebook PC, a personal digital assistant (PDA), or the like.

Recently, a display including a micro LED having a size of 100 μm or less has been developed. A micro LED has higher reaction speed, lower power consumption, and higher luminance as compared to a conventional LED and thus is considered as a light-emitting device for a next generation display.

In a large format micro LED display in which a plurality of LEDs emitting different colors like red (R), green (G), and blue (B) are arranged, a white balance of a front surface as well as a white balance of a side surface of the screen are important. However, in an RGB micro LED, due to a difference of structures and a difference of a refractive index by a difference of a property of a matter, luminous intensity distribution of field of view by angles may be different. As a result, there may be a problem in that white balance is not maintained since luminous intensity of a specific color becomes high at a specific field of view.

### SUMMARY

Provided is a display module that may compensate different fields of view by angles of RGB micro light-emitting diodes (LEDs).

Additional aspects will be set forth in part in the description which follows and, in part, will be apparent from the description, or may be learned by practice of the presented embodiments.

According to an aspect of the disclosure, a display module may include a substrate, a plurality of LEDs provided on the substrate, an adhesive layer provided on a first surface of the substrate on which the plurality of LEDs are provided, and an optical film connected to the substrate by the adhesive layer and configured to increase luminous intensity by scattering light emitted by the plurality of LEDs.

The optical film may include a light scattering layer comprising a plurality of light diffusing portions configured to scatter light emitted by the plurality of LEDs and a protective layer provided on the light scattering layer.

The light scattering layer may include a plurality of black matrices, and the plurality of light diffusing portions may be provided between the plurality of black matrices and at locations corresponding to the plurality of LEDs.

The plurality of LEDs may include a first LED configured to emit light of a first color and a second LED configured to emit light of a second color that is different from the first color.

The plurality of light diffusing portions may include a first light diffusing portion corresponding to the first LED and configured to maintain a first luminous intensity of the first LED at a constant intensity by scattering the light of the first color emitted by the first LED and a second light diffusing portion corresponding to the second LED and configured to maintain a second luminous intensity of the second LED at a constant intensity by scattering the light of the second color emitted by the second LED.

The first light diffusing portion may include a first resin layer and at least one first scattering particle provided in the first resin layer at a first concentration and the second light diffusing portion may include a second resin layer and at least one second scattering particle provided in the second resin layer at a second concentration that is different from the first concentration.

The first scattering particle may include at least one of TiO₂, ZrO₂, Al₂O₃, In₂O₃, ZnO, SnO₂, Sb₂O₃, and ITO, and the second scattering particle may include at least one of TiO₂, ZrO₂, Al₂O₃, In₂O₃, ZnO, SnO₂, Sb₂O₃, and ITO.

The display module may satisfy

$$\frac{1}{{L}_{MFP}} = μ * ρ ,$$

where a ρ is the first concentration of the at least one first scattering particle or the second concentration of the at least one second scattering particle, L_{MFP} is a mean-free path length between each scattering particle, and μ is a Mie scattering coefficient.

The first light diffusing portion may include a first resin layer having a first surface roughness and the second light diffusing portion may include a second resin layer having a second surface roughness that is different from the first surface roughness.

The first resin layer may include a plurality of first protrusions protruding from a surface of the first resin layer, the second resin layer may include a plurality of second protrusions protruding from a surface of the second resin layer, and the plurality of first protrusions and the plurality of second protrusions may be provided in a random or quasi-random manner.

The first resin layer comprises a plurality of first concave portions on a surface of the first resin layer, the second resin layer comprises a plurality of second concave portions on a surface of the second resin layer, and the plurality of first concave portions and the plurality of second concave portions are provided in a random or quasi-random manner.

A size of each of the plurality of LEDs may be less than or equal to 50 μm, and the display module may satisfy p−m−2a>0, where m is a size of an LED of the plurality of LEDs, p is a distance between adjacent LEDs of the plurality of LEDs, and 2a is the difference between the size of an LED and a light diffusing portion of the first light diffusing portion and the second light diffusing portion.

The adhesive layer may include a pressure sensitive adhesive (PSA)-based material.

The adhesive layer may include polyimide (PI), polyurethane acrylate (PUA), or polyacrylate (PA).

The display module may further include an anisotropic conductive film (ACF) having a black-based color and provided between the first surface of the substrate and the adhesive layer.

According to an aspect of the disclosure, a display module may include a substrate, an LED provided on the substrate, an adhesive layer on a surface of the substrate on which the LED is provided, and an optical film connected to the substrate by the adhesive layer and configured to increase luminous intensity by scattering light emitted by the LED, where the optical film may include a light scattering layer comprising a light diffusing portion configured to scatter light emitted by the LED.

The light scattering layer may include a first black matrix provided at a first side of the light diffusing portion and a second black matrix provided at a second side of the light diffusing portion.

The display module may satisfy

$$\frac{1}{{L}_{MFP}} = μ * ρ ,$$

where a ρ is a concentration of a scattering particle of the light diffusing portion, L_{MFP} is a mean-free path length between each scattering particle, and μ is a Mie scattering coefficient.

The light diffusing portion may include a resin layer and a plurality of protrusions protruding from a surface of the resin layer, where the plurality of protrusions may be provided in a random or quasi-random manner.

According to an aspect of the disclosure, a display module may include a substrate, a plurality of LEDs provided on the substrate, an adhesive layer provided on a first surface of the substrate on which the plurality of LEDs are provided, and an optical film connected to the substrate by the adhesive layer and configured to increase luminous intensity by scattering light emitted by the plurality of LEDs, where the optical film may include a light scattering layer including a plurality of light diffusing portions provided at locations corresponding to the plurality of LEDs and configured to scatter light emitted by respective LEDs of the plurality of LEDs and a plurality of black matrices between the plurality of light diffusing portions.

### BRIEF DESCRIPTION OF THE DRAWINGS

The above and other aspects, features, and advantages of certain embodiments of the present disclosure will be more apparent from the following description taken in conjunction with the accompanying drawings, in which:

FIG. 1 is a block diagram illustrating a display apparatus according to an embodiment of the disclosure;

FIG. 2 is a diagram illustrating a display substrate according to an embodiment of the disclosure;

FIG. 3 is an enlarged view of portion ‘A” of FIG. 2 according to an embodiment of the disclosure;

FIG. 4 is a diagram illustrating a threshold angle of light emitted by a light emitting diode and an adhesive layer of a display substrate according to an embodiment of the disclosure;

FIG. 5 is a graph illustrating a relation of a threshold angle according to thickness of the adhesive layer, according to an embodiment of the disclosure;

FIG. 6 is a cross-sectional view illustrating a light diffusing portion of a display substrate according to an embodiment of the disclosure;

FIG. 7 is a plan view illustrating a light diffusing portion of a display substrate according to an embodiment of the disclosure; and

FIG. 8 is a cross-sectional view illustrating a light diffusing portion of a display substrate according to an embodiment of the disclosure.

### DETAILED DESCRIPTION

Hereinafter, various embodiments will be described in detail with reference to the accompanying drawings. The embodiments described herein may be variously modified. Specific embodiments are depicted in the drawings and may be described in detail in the description of the disclosure. However, it is to be understood that the particular embodiments disclosed in the appended drawings are for ease of understanding of various embodiments. Therefore, it is intended that the disclosure not be limited to the particular embodiments disclosed in the accompanying drawings, but on the contrary, the intention is to cover all equivalents or alternatives falling within the spirit and scope of the disclosure.

Terms such as “first,” “second,” and the like may be used to describe various components, but the components should not be limited by the terms. The terms are used to distinguish a component from another.

It is to be understood that the terms such as “comprise” or “consist of” are used herein to designate a presence of a characteristic, number, step, operation, element, component, or a combination thereof, and do not to preclude a presence or a possibility of adding one or more of other characteristics, numbers, steps, operations, elements, components or a combination thereof. It will be understood that when an element is referred to as being “coupled” or “connected” to another element, there may be other elements in the middle, although it may be directly coupled or connected to the other element. In contrast, when an element is referred to as being “directly coupled to” or “directly connected to” another element, there are no elements present therebetween.

In the disclosure, “the same” may refer to components that are matched as well as those that may be different within an extent of the processing error range.

A display module may include a display substrate including an inorganic light emitting diode (LED) for displaying an image. The display substrate may be a planar display substrate or a curved display substrate. For example, in a display substrate, a plurality of inorganic LEDs having a size of 100 μm or less are mounted, the display substrate may provide better contrast, response time, and energy efficiency as compared to a liquid crystal display (LCD) requiring a backlight.

The micro LED mounted on a display substrate of the disclosure has brightness, luminous efficiency, and lifetime longer than the organic LED (OLED). The micro LED may be a semiconductor chip capable of emitting light by itself when power is supplied. The micro LED has a fast reaction rate, low power, and high luminance. That is, the micro LED may have higher efficiency of converting electricity into a photon in comparison with an LCD or an OLED. The micro LED may have higher “brightness per Watt” as compared to LCD or OLED displays. The micro LED may provide the same brightness while consuming less about substantially half energy as the LED exceeding 100 μm or OLED. The micro LEDs are capable of providing high resolution, outstanding color, contrast and brightness, may accurately provide a wide range of colors, and may provide a clear screen even in the outdoors brighter than indoors. In addition, the micro LEDs are resistant to burn-in phenomenon, and generate less heat, thereby improving product lifespan without deformation. The micro LED may have a flip chip structure in which an anode and a cathode electrode are disposed on the same surface and a light emitting surface is located the opposite surface wherein the anode electrode and the cathode electrode are formed.

According to an embodiment, the display substrate may be a glass substrate, a synthetic resin series having a flexibility material (for example, polyimide (PI), polyethylene terephthalate (PET), polyethersulfone (PES), polyethylene naphthalate (PEN), polycarbonate (PC), etc.) or a ceramic substrate.

In a front surface of the display substrate, a thin film transistor (TFT) circuit may be formed and in a rear surface of the substrate, a power supply circuit for providing power to the TFT circuit, a data driving driver, a gate driving driver, and a timing controller for controlling each driving driver may be disposed. A plurality of pixels arranged on a front surface of the substrate may be driven by the TFT circuit.

A circuitry may not be disposed in a rear surface of the display substrate. In this case, a TFT circuit may be made of a film form and attached to a front surface of the display substrate (in this case, the display substrate may be a glass substrate).

According to various embodiments, the TFT provided to a display substrate is not limited to a specific structure or type. In other words, the TFT may be implemented as amorphous silicon (a-Si) TFT, a low temperature polycrystalline silicon (LTPS) TFT, low temperature polycrystalline oxide (LTPO) TFT, hybrid oxide and polycrystalline silicon (HOP) TFT, liquid crystalline polymer (LCP) TFT, organic TFT (OTFT), or a graphene TFT. Alternatively, the display substrate may be applied to a P type (or N-type) MOSFET in a Si wafer complementary metal-oxide-semiconductor (CMOS) process.

The front surface of the display substrate may be divided into an active region and an inactive region. The active region may be a region in which a TFT layer occupies in the front surface of the display substrate, and the inactive region may be a region except for the region in which a TFT layer occupies in the front surface of the display substrate.

A display substrate may include an edge region corresponding to an outer portion. The edge region of the display substrate may be the outermost region of the glass substrate. The edge region of the display substrate may be a remaining region except for the region in which the circuit of the display substrate is formed. The edge region of the display substrate may also include a portion of the front surface of the display substrate adjacent to the side of the display substrate and a rear surface of the display substrate adjacent to the side of the display substrate. The display substrate may be formed of a quadrangle type. For example, the display substrate may be formed of rectangle or square. The edge region of the display substrate may include at least one of four sides of the display substrate.

The display substrate may not have a TFT layer. In this case, the display substrate may include a plurality of micro integrated circuits (ICs) that may function as a TFT. The display substrate may have wiring electrically connecting a plurality of micro ICs and micro LEDs.

The pixel driving method of the display module may be an active matrix (AM) driving method or a passive matrix (PM) driving method. The display module may form a pattern of wiring in which each micro LED is electrically connected according to an AM driving method or a PM driving method.

The display module may be installed and applied to wearable devices, portable devices, handheld devices in a single unit, and electronic products or electronic parts requiring various displays, and may be applied to display devices such as monitors for personal computer, high-resolution televisions (TVs) and signage (or digital signage), electronic displays, etc. through a plurality of assembly layouts, as a matrix type.

Hereinafter, example embodiments of the disclosure will be described in detail with reference to the accompanying drawings. The same reference numerals are used for the same components in the drawings, and redundant descriptions thereof will be omitted. The embodiments described herein are example embodiments, and thus, the disclosure is not limited thereto and may be realized in various other forms. It is to be understood that singular forms include plural referents unless the context clearly dictates otherwise. The terms including technical or scientific terms used in the disclosure may have the same meanings as generally understood by those skilled in the art.

Hereinafter, a display apparatus according to some embodiments of the disclosure will be described with reference to the drawings.

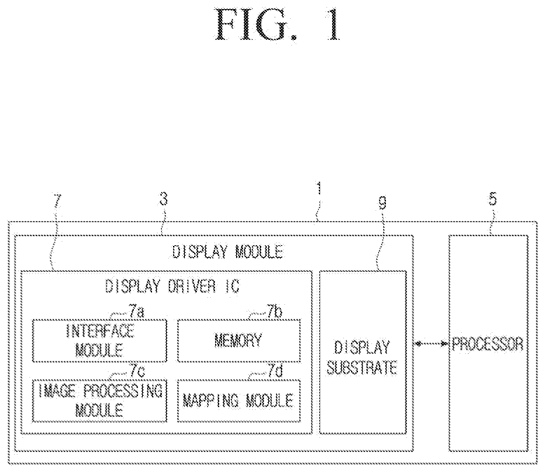

FIG. 1 is a block diagram illustrating the display apparatus according to one embodiment of the disclosure.

A display apparatus 1 may include a plurality of display modules 3. The plurality of display modules 3 may be physically connected to implement a large display (e.g., large format display).

Referring to FIG. 1, the display apparatus 1 according to some embodiments of the disclosure may include a display module 3 and a processor 5.

The display module 3 according to some embodiments of the disclosure may display various images. The image may refer to a still image and/or a moving image. The display module 3 may display various images such as a broadcast content and a multimedia content. In addition, the display module 3 may display a user interface and an icon.

The display module 3 may include a display panel 9 and a display driver integrated circuit (IC) 7 for controlling the same.

The display driver IC 7 may include an interface module 7a, a memory 7b (e.g., a buffer memory), an image processing module 7c, and a mapping module 7d. The display driver IC 7 may receive image information including image data, or an image control signal corresponding to a command for controlling the image data from another component of the display apparatus 1 through the interface module 7a. According to one or more embodiments, the image information may be received from the processor 5 (e.g., a main processor (e.g., an application processor) or a secondary processor (e.g., a graphics processing unit (GPU)) operating independently of the function of the main processor).

The display driver IC 7 may communicate with the sensor module through the interface module 7a. The display driver IC 7 may store at least a portion of the received image information in the memory 7b (e.g., in a frame unit). The image processing module 7c may perform pre-processing or post-processing (e.g., resolution, brightness, or size adjustment) for at least a part of the image data based on at least one of the characteristics of the image data or characteristics of the display panel 9. The mapping module 7d may generate a voltage value or a current value corresponding to the image data pre-processed or post-processed through the image processing module 7c. According to one or more embodiments, the generation of a voltage value or current value may be performed based at least in part on an attribute of pixels of the display panel 9 (e.g., an array of pixels (RGB stripe or PenTile structure), or a size of each of the subpixels). At least some pixels of the display panel 9 may be driven based at least in part on the voltage value or current value such that visual information (e.g., text, an image, or an icon) corresponding to the image data may be displayed through the display panel 9.

The display driver IC 7 may transmit a drive signal (for example, a driver drive signal or a gate drive signal) to the display based on the image information received from the processor 5.

The display driver IC 7 may display an image based on an image signal received from the processor 5. For example, the display driver IC 7 may generate a drive signal for a plurality of sub-pixels based on an image signal received from the processor 5, and display an image by controlling light emission of the plurality of sub-pixels based on the drive signal.

The display module 3 further includes a touch circuit. The touch circuit includes a touch sensor and a touch sensor IC for controlling the same. The touch sensor IC may control the touch sensor to detect a touch input or hovering input for the designated position of the display panel 9. For example, the touch sensor IC may detect a touch input or hovering input by measuring the change in the signal (e.g., voltage, light amount, resistance, or charge) for the designated position of the display panel 9. The touch sensor IC may provide information about the detected touch input or hovering input (e.g., location, area, pressure, or time) to the processor 5. At least part of the touch circuit (e.g., the touch sensor IC) may be included as part of the display driver IC 7, or as part of the display substrate 10, or other components (e.g., secondary processor) placed outside of the display module 3.

The processor 5 may be implemented by a digital signal processor (DSP) that processes a digital image signal, a microprocessor, a GPU, an artificial intelligence (AI) processor, a neural processing unit (NPU), or a time controller (TCON). However, the processor 5 is not limited thereto, and may include one or more of a central processing unit (CPU), a micro controller unit (MCU), a micro processing unit (MPU), a controller, an application processor (AP), a communication processor (CP), and an advanced reduced instruction set computer (RISC) machine (ARM) processor, or may be defined by these terms. In addition, the processor 5 may be implemented by a system-on-chip (SoC) or a large scale integration (LSI) in which a processing algorithm is embedded or may be implemented in the form of an application specific integrated circuit (ASIC) or a field programmable gate array (FPGA).

The processor 5 may drive an operating system or an application program to control hardware or software components connected to the processor 5, and may perform various types of data processing and computation. In addition, the processor 5 may load and process a command or data received from at least one of other components into a volatile memory, and store various data in a non-volatile memory.

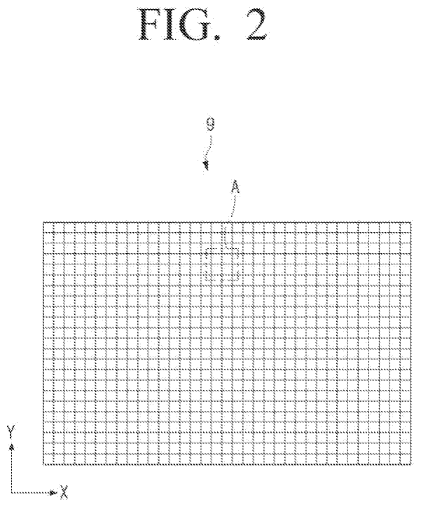

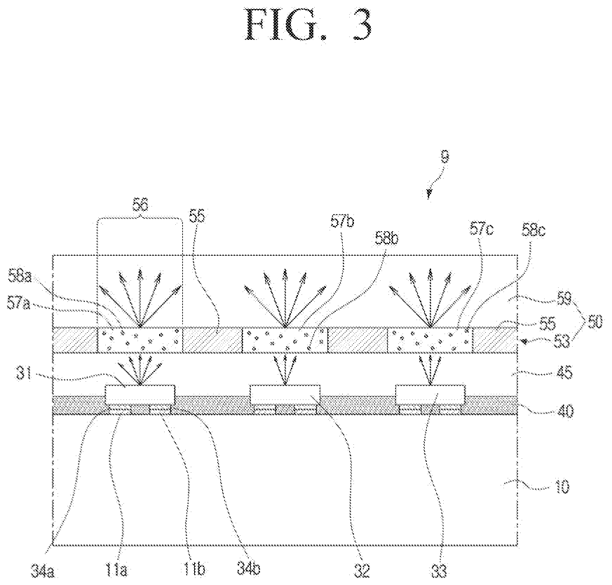

FIG. 2 is a diagram illustrating a display panel according to an embodiment of the disclosure. FIG. 3 is an enlarged view of portion ‘A” of FIG. 2 according to an embodiment of the disclosure.

Referring to FIGS. 2 and 3, the display panel 9 may include a display substrate 10 (also referred to as “substrate”) and a plurality of pixels. On the substrate 10, a pixel region in which a plurality of pixels are arranged may be disposed in a form of a grid.

In each pixel region, pixels may be disposed one by one. One pixel may include a plurality of sub-pixels. For example, the plurality of sub-pixels may include a first LED 31 that emits light in a red wavelength band, a second LED 32 that emits light in a green wavelength band, and a third LED 33 that emits light in a blue wavelength band. The first, second, and third LEDs 31, 32, 33 may be, for example, micro LEDs having a size of 100 μm or less as an inorganic light emitting device. In this case, the first, second, and third LEDs 31, 32, 33 may be a flip-chip type in which a first electrode pad 34a (e.g., anode electrode pad) and a second electrode pad 34b (e.g., cathode electrode pad) are disposed together on an opposite side of a light emitting surface.

In one pixel region, at a portion where the first, second, and third LEDs 31, 32, 33 are not occupied, a plurality of TFTs to drive the first, second, and third LEDs 31, 32, 33 may be disposed.

The first, second, and third LEDs 31, 32, and 33 may be arranged in a line at regular intervals in one pixel region, but are not limited thereto. For example, the first, second, and third LEDs 31, 32, and 33 may be arranged in an L-letter shape or in a pentile RGBG layout. The pentile RGBG layout is a layout in which the sub-pixels are arranged in such a way that the numbers of red, green, and blue sub-pixels are at a ratio of 1:1:2 (RGBG) based on a cognitive characteristic that a person identifies green better than blue. The pentile RGBG layout may enable an increase in yield and a reduction in unit cost, and enable implementation of a high resolution on a small screen, and thus is effective.

The first LED 31 may include a first semiconductor layer, a second semiconductor layer, an active layer provided between the first semiconductor layer and the second semiconductor layer, a first electrode pad, and a second electrode pad. The first semiconductor layer, the active layer, and the second semiconductor layer may be formed by using a method such as metal organic chemical vapor deposition, chemical vapor deposition, or plasma-enhanced chemical vapor deposition.

The first semiconductor layer may include, for example, a p-type semiconductor layer (anode). The p-type semiconductor layer may be one of, for example, GaAs, GaP, GaAlAs, or InGaAlP.

The active layer is a region in which electrons and holes are recombined. The active layer may transition to a low energy level by recombination of electrons and holes, and may generate light having a corresponding wavelength. The active layer may include a semiconductor material such as amorphous silicon or poly crystalline silicon. Alternatively, the active layer may include an organic semiconductor material, and may be formed in a single quantum well (SQW) structure or a multi quantum well (MQW) structure.

The second semiconductor layer may include, for example, n-type semiconductor layer (cathode). The n-type semiconductor layer may be one of, for example, GaAs, GaP, GaAlAs, or InGaAlP.

The first electrode pad 34a may be connected to the first semiconductor layer and may be formed of an opaque metal (e.g., Al, Pt, Au, Cu, or Cr). The first electrode pad, when the first LED 31 is transferred on the display substrate 10, may be electrically and physically connected to the first panel electrode 11a disposed on the display substrate 10.

The second electrode pad 34b may be connected to the second semiconductor layer and may be formed of an opaque metal (e.g., Al, Pt, Au, Cu, or Cr). The second electrode pad, when the first LED 101 is transferred on the display substrate 10, may be electrically and physically connected to the second panel electrode 11b disposed on the display substrate 10.

The structure of the second and third LEDs 32, 33 may be substantially the same as the structure of the first LED 31.

A black anisotropic conductive film (ACF) 40 may be attached to a surface of the display substrate 10 where the first, second, and third LEDs 31, 32, 33 are mounted. The black ACF 40 may prevent light emitted by first, second, and third LEDs 31, 32, 33 from passing or reflecting from an adjacent LED, thereby improving an aspect ratio of the display panel 9.

The black ACF 40 may include a thermosetting material having a black-based color and a plurality of conductive balls. The thermosetting material may be, for example, a resin composed of an epoxy resin, a polyurethane, or an acrylic resin. The thermosetting material may have a black color or a color similar to black to absorb light. The plurality of conductive balls have conductivity and may have a fine size, for example, a diameter of about 3 to 15 μm. The plurality of conductive balls may occupy approximately 0.5% to 5% out of the total volume of the black ACF 40. The plurality of conductive balls may include polymer particles and a conductive metal film (e.g., Au, Ni, or Pd) coated on an outer circumferential surface of the polymer particles.

The black ACF 40 may be attached to the display substrate 10 before the first, second, and third LEDs 31, 32, 33 are mounted on the display substrate 10. In this case, the plurality of first panel electrodes 11a and the plurality of second panel electrodes 11b arranged on the display substrate 10 may be covered by the black ACF 40.

The first, second, and third LEDs 31, 32, 33, after being transferred to the display substrate 10 to which the black ACF 40 is attached, may be pressed toward the display substrate 10 at a preset pressure through a thermal compression process. The black ACF 40 may be under filled by flowing between the bottom surface of the first, second, and third LEDs 31, 32, 33 and the upper surface of the display substrate 10 while having fluidity by high temperature heat generated during the thermal compression process, and may be arranged to surround the first, second, and third LEDs 31, 32, 33. The black ACF 40 may be formed to have a height lower than a light emitting surface of the first, second, and third LEDs 31, 32, 33. While the black ACF 40 is cured, the first, second, and third LEDs 31, 32, 33 may be fixed to the display substrate 10 firmly.

In the display panel 9 according to some embodiments of the disclosure, a transparent ACF may be utilized instead of the black ACF 40.

The display panel 9 may include an optical film 50 covering the first, second, and third LEDs 31, 32, 33 and an adhesive layer 45 to attach the optical film 50 to the display substrate 10.

The adhesive layer 45 may cover the first, second, and third LEDs 31, 32, 33 and one surface of the display substrate 10 on which and the first, second, and third LEDs 31, 32, 33 are mounted. The adhesive layer 45 may be a pressure sensitive adhesive (PSA)-based material. The PSA may be an adhesive on which an adhesive material acts when a predetermined pressure is applied to adhere to an adherence surface (e.g., a surface of the plurality of LEDs 31, 32, 33 and the black ACF 40).

On the adhesive layer 45, an inorganic layer for preventing permeance of oxygen may be coated. The inorganic layer may be made of an inorganic material such as SiO₂ or SiN.

The optical film 50 may include a light scattering layer 53 and a protective layer 59 laminated on the light scattering layer 53. The light scattering layer 53 may optically compensate a problem that fields of view are different by angles according to the first, second, and third LEDs 31, 32, 33 emitting different colors of light.

The light scattering layer 53 may include a plurality of black matrices, such as black matrix 55, to prevent crosstalk in which different colors of light emitted by adjacent LEDs are mixed.

The black matrix 55 may improve optical efficiency and color reproducibility of the display panel 9 by absorbing light incident on the front direction of the display panel 9. The black matrix 55 may be made of a resin composite including a black pigment. The black matrix 55 may block crosstalk by preventing that different colors of light emitted by light scattering portions adjacent from each other are mixed.

The light scattering layer 53 may include a plurality of light diffusing portions disposed between the black matrices 55 (such as light diffusing portion 56). The plurality of light diffusing portions may correspond to the first, second, and third LEDs 31, 32, 33, respectively. The plurality of light diffusing portions may include a first resin layer 57a corresponding to the first LED 31, scattering particles, such as a first scattering particle 58a, distributed in the first resin layer 57a, a second resin layer 57b corresponding to the second LED 32 and scattering particles, such as a second scattering particle 58b, distributed in the second resin layer 57b, a third resin layer 57c corresponding to the third LED 33, and scattering particles, such as a third scattering particle 58c, distributed in the third resin layer 57c.

The first, second, and third scattering particles 58a, 58b, 58c may include at least one of TiO₂, ZrO₂, Al₂O₃, In₂O₃, ZnO, SnO₂, Sb₂O₃, or ITO. The size of the first, second, and third scattering particles 58a, 58b, 58c may be around 50 nm to several μm. The diameters of the first, second, and third scattering particles 58a, 58b, 58c may be smaller than each thickness of the first, second, and third resin layers 57a, 57b, 57c.

The first scattering particle 58a may make a Lambertian distribution by scattering red light emitted by the first LED 31. Accordingly, the luminance of the surface (the surface contacting the protective layer 59) of the first resin layer 57a may have isotropic properties. Similarly, the second scattering particle 58b may make the Lambertian distribution by scattering green light emitted by the second LED 32. The luminance at the surface (the surface contacting the protective layer 59) of the second resin layer 57b may have isotropic properties. The third scattering particles 58c may make the Lambertian distribution by scattering blue light emitted by the third LED 33. The luminance of the surface (a surface contacting the protective layer 59) of the third resin layer 57c may have isotropic properties.

The light emitted by the first, second, and third LEDs 31, 32, 33 may have the Lambertian distribution as the light is scattered by a plurality of light scattering portions. Therefore, issues caused by the white balance associated with fields of view not being maintained according to luminous intensity of the first, second, and third LEDs 31, 32, 33 may be prevented and/or resolved.

Hereinbelow, the adhesive layer 45 and the optical film 50 will be described in greater detail.

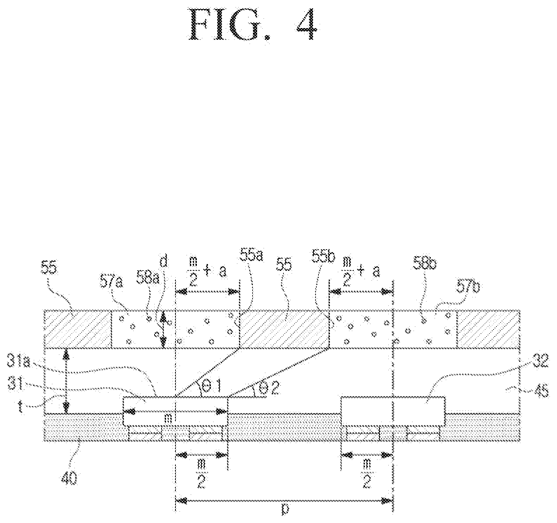

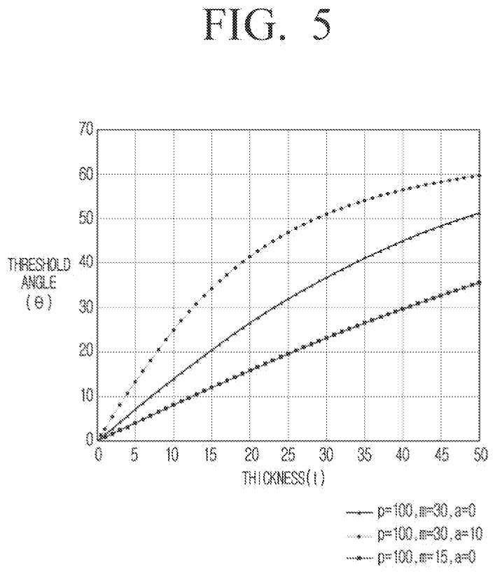

FIG. 4 is a diagram illustrating a threshold angle of light emitted by a LED and an adhesive layer of a display panel according to an embodiment of the disclosure. FIG. 5 is a graph illustrating a relation of a threshold angle according to thickness of the adhesive layer according to an embodiment of the disclosure.

Referring to FIG. 4, the thickness t of the adhesive layer 45 may affect the angles θ1, θ2 of light reaching the black matrix 55 as the light emitted by the light emitting surface 31a of the first LED 31 is refracted by the Snell's law. In this case, a factor that may affecting the angles θ1, θ2 of the light may be thickness t of the adhesive layer 45, a distance (or a distance between sub-pixels) p between adjacent LEDs 31, 32, a size m of the LED, and a difference 2a between the size of the LED and the light diffusing portion.

The relation among the size (m) of the LED having a size of 100 μm or below (e.g., m<50 μm), distance (p) between adjacent LEDs, and a difference (2a) between the size of the LED and the light diffusing portion satisfies Equation (1).

p−m−2a>0 (1)

The size (m+2a) of the light diffusing portion according to Equation (1) may be different depending on the thickness t of the adhesive layer 45.

The relationship between the thickness t of the adhesive layer 45 and the angle of the light emitted by the LED is as illustrated in FIG. 5. Referring to FIG. 5, as the size of the LED is smaller, and the smaller the size difference 2a of the light diffusing portion and the LED, a greater thickness t may be allowed. As lower thickness t of the adhesive layer 45 may be more advantageous for manufacturing the display panel 9.

When the angles (θ1, θ2) of the light emitted by the light emitting surface 31a of the LED 31 are less than or equal to about 10 degrees, the field of view may be improved. Accordingly, referring to FIG. 5, the thickness t of the adhesive layer 45 may be less than or equal to about 12 μm in order for the angle (θ1, θ2) of the light to be less than or equal to about 10 degrees.

Referring to FIG. 4, the thickness d of the light diffusing portion may be about 10 μm to 50 μm. The thickness d of the light diffusing portion may be the thickness of the first resin layer 57a.

The concentration of the first scattering particles 58a may determine a mean-free path length (L_{MFP}) between the particles. In this case, as the concentration ρ of the first scattering particle 58a increases as shown in Equation (2) below, the L_{MFP} may be shortened.

$$\frac{1}{{L}_{MFP}} = μ * ρ \qquad ( 2 )$$

where, μ is a Mie scattering coefficient.

When the thickness d of the light diffusing portion is about 1 μm to 50 μm, the L_{MFP} of the first scattering particle 58a may be about 0.000333 mm to 0.5 mm. An approximate concentration ρ of the first scattering particle 58a may be about 1.5*108 mm⁻³ to 2.3*1011 mm⁻³.

The optical film 50 may be attached to the display substrate 10 through the adhesive layer 45 in a state in which the first, second, and third LEDs 31, 32, 33 are mounted on the black ACF 40. In this case, the plurality of light diffusing portions of the optical film 50 are aligned with the plurality of LEDs of the corresponding display substrate 10 before attaching the optical film 50 to the display substrate 10. When the alignment between the display substrate 10 and the optical film 50 is completed, the optical film 50 may be attached to the display substrate 10 in a lamination manner.

As such, the optical film 50 may be formed in the form of a sheet in which a light scattering layer 53 and a protective layer 59 are laminated, and thus may be attached to the display substrate 10 by a lamination method. However, the optical film 50 may be formed on the display substrate 10 by an inkjet method.

For example, the adhesive layer 45 may be formed to be planarized through a coating process or a deposition process on the display substrate 10 on which the first, second, and third LEDs 31, 32, 33 are mounted. In this case, the upper surface of the adhesive layer 45 on which the light scattering layer 53 is to be laminated may be planarized. The adhesive layer 45 may include a base resin, a coupling agent, and a photoinitiator.

When the adhesive layer 45 is formed by a coating process, the material of the adhesive layer 45 may be a polymer organic material. The polymer organic material may be polyimide (PI), polyurethane acrylate (PUA), or polyacrylate (PA). When the adhesive layer 45 is formed by a deposition process, the material of the adhesive layer 45 may be an inorganic material.

The light scattering layer 53 may be formed on the upper surface of the planarized adhesive layer 45 by an inkjet printing method. For example, the black matrix 55 may be formed on the upper surface of the adhesive layer 45 to be cured. Subsequently, a plurality of light diffusing portions may be formed by discharging the resin included in the scattering particles in a grid-shaped space formed by the black matrix 55 by an inkjet printing method. In this case, scattering particles having a proper concentration may be included in the resin of the corresponding light diffusing portion in consideration of the characteristics of the RGB LED.

After the light scattering layer 53 is cured, the protective layer 59 may be attached to the upper surface of the light scattering layer 53 in a lamination method.

In order to scatter the light emitted by the first, second, and third LEDs 31, 32, 33, the light diffusing portion may include scattering particles in the resin. However, the light diffusing portion is not limited to such a configuration, and may be configured to adjust the surface roughness of the resin layer included in the light diffusing portion. Hereinafter, a structure of a light diffusion unit will be described with reference to the drawings.

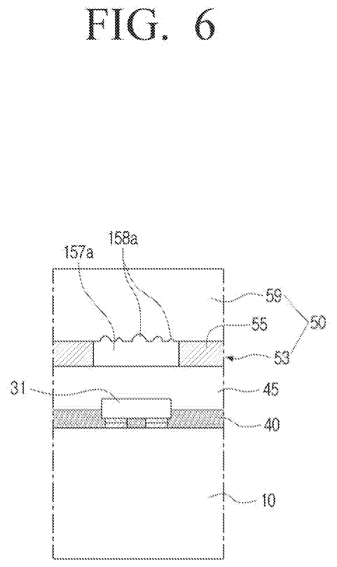

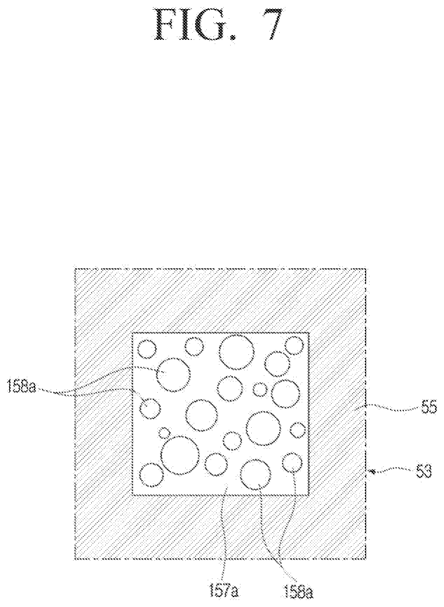

FIG. 6 is a cross-sectional view illustrating a light diffusing portion of a display panel according to an embodiment of the disclosure. FIG. 7 is a plan view illustrating a light diffusing portion of a display panel of FIG. 6 according to an embodiment of the disclosure.

Referring to FIGS. 6 and 7, the light diffusing portion may include the resin layer 157a and a plurality of protrusions 158a formed on the surface of the resin layer 157a. The protrusions 158a may be formed to protrude from the surface of the resin layer 157a.

The surface roughness of the resin layer 157a may be increased by a plurality of protrusions 158a. The plurality of protrusions 158a may have a shape similar to a shape of an approximately convex lens. The size of the plurality of protrusions 158a may be up to about tens of nanometers to several micrometers. All or a part of the plurality of protrusions 158a arranged on the surface of the resin layer 157a may have different sizes. The plurality of protrusions 158a may have different heights protruding from the surface of the resin layer 157a. The plurality of protrusions 158a may be arranged on the surface of the resin layer 157a in a random or quasi-random manner.

A plurality of protrusions 158a may scatter light emitted by the first LED 31 and incident on the resin layer 157a. Therefore, the plurality of protrusions 158a may correspond to the first, second, and third scattering particles 58a, 58b, 58c described above.

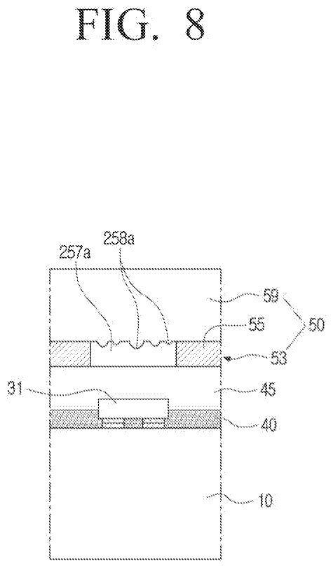

FIG. 8 is a cross-sectional view illustrating a light diffusing portion of a display panel according to an embodiment of the disclosure.

Referring to FIG. 8, the light diffusing portion may include the resin layer 257a and a plurality of concave portions 258a formed on the surface of the resin layer 257a. The plurality of concave portions 258a may be formed to be concave in the inward direction of the resin layer 275a from the surface of the resin layer 257a. The plurality of concave portions 258a may be arranged on the surface of the resin layer 257a in a random or quasi-random manner.

Before the optical film 50 is attached to the display substrate 10, different scattering structures may be applied for each RGB LED by measuring the luminous intensity for each angle for each RGB LED mounted on the display substrate 10. For example, if light of a specific color emitted by the RGB LED is seriously out of the Lambertian distribution, the thickness of the light scattering layer 53, the concentration of the scattering particles, or the surface roughness of the resin layer may be appropriately adjusted so that the Lambertian distribution is made by increasing the scattering intensity for light of a specific color. Accordingly, light emitted by each of the RGB may have the same light intensity after passing through the optical film 50.

The display panel 9 according to an embodiment of the disclosure may compensate for a difference in the refractive index of the RGB LED according to the physical property difference by the optical film 50, thereby maintaining the front white balance of the screen and the side white balance of the screen. Therefore, the display panel 9 according to an embodiment of the disclosure may improve field of view for each angle.

The embodiments of the disclosure disclosed in the specification and the drawings provide merely specific examples to easily describe technical content according to the embodiments of the disclosure and help the understanding of the embodiments of the disclosure, not intended to limit the scope of the embodiments of the disclosure. Accordingly, the scope of various embodiments of the disclosure should be interpreted as encompassing all modifications or variations derived based on the technical spirit of various embodiments of the disclosure in addition to the embodiments disclosed herein.

What is claimed is:

1. A display module comprising:
a substrate;
a plurality of light emitting diodes (LEDs) provided on the substrate;
an adhesive layer provided on a first surface of the substrate on which the plurality of LEDs are provided; and
an optical film coupled to the substrate by the adhesive layer and configured to increase luminous intensity by scattering light emitted by the plurality of LEDs.

2. The display module of claim 1, wherein the optical film comprises:
a light scattering layer comprising a plurality of light diffusing portions configured to scatter light emitted by the plurality of LEDs; and
a protective layer provided on the light scattering layer.

3. The display module of claim 2, wherein the light scattering layer comprises a plurality of black matrices, and
wherein the plurality of light diffusing portions are provided between the plurality of black matrices at locations corresponding to the plurality of LEDs.

4. The display module of claim 3, wherein the plurality of LEDs comprises:
a first LED configured to emit light of a first color; and
a second LED configured to emit light of a second color that is different from the first color.

5. The display module of claim 4, wherein the plurality of light diffusing portions comprises:
a first light diffusing portion corresponding to the first LED and configured to maintain a first luminous intensity of the first LED at a constant intensity by scattering the light of the first color emitted by the first LED; and
a second light diffusing portion corresponding to the second LED and configured to maintain a second luminous intensity of the second LED at a constant intensity by scattering the light of the second color emitted by the second LED.

6. The display module of claim 5, wherein the first light diffusing portion comprises a first resin layer and at least one first scattering particle provided in the first resin layer at a first concentration, and
wherein the second light diffusing portion comprises a second resin layer and at least one second scattering particle provided in the second resin layer at a second concentration that is different from the first concentration.

7. The display module of claim 6, wherein the at least one first scattering particle comprises at least one of TiO₂, ZrO₂, Al₂O₃, In₂O₃, ZnO, SnO₂, Sb₂O₃, and ITO, and
wherein the at least one second scattering particle comprises at least one of TiO₂, ZrO₂, Al₂O₃, In₂O₃, ZnO, SnO₂, Sb₂O₃, and ITO.

8. The display module of claim 6, wherein the display module satisfies
$$\frac{1}{{L}_{MFP}} = μ * ρ ,$$
where a ρ is the first concentration of the at least one first scattering particle or the second concentration of the at least one second scattering particle, L_{MFP} is a mean-free path length between each scattering particle, and μ is a Mie scattering coefficient.

9. The display module of claim 5, wherein the first light diffusing portion comprises a first resin layer having a first surface roughness, and
wherein the second light diffusing portion comprises a second resin layer having a second surface roughness that is different from the first surface roughness.

10. The display module of claim 9, wherein the first resin layer comprises a plurality of first protrusions protruding from a surface of the first resin layer,
wherein the second resin layer comprises a plurality of second protrusions protruding from a surface of the second resin layer, and
wherein the plurality of first protrusions and the plurality of second protrusions are provided in a random or quasi-random manner.

11. The display module of claim 9, wherein the first resin layer comprises a plurality of first concave portions on a surface of the first resin layer,
wherein the second resin layer comprises a plurality of second concave portions on a surface of the second resin layer, and
wherein the plurality of first concave portions and the plurality of second concave portions are provided in a random or quasi-random manner.

12. The display module of claim 9, wherein a size of each of the plurality of LEDs is less than or equal to 50 μm, and
wherein the display module satisfies p−m−2a<0, where m is a size of an LED of the plurality of LEDs, p is a distance between adjacent LEDs of the plurality of LEDs, and 2a is the difference between the size of an LED and a light diffusing portion of the first light diffusing portion and the second light diffusing portion.

13. The display module of claim 1, wherein the adhesive layer comprises a pressure sensitive adhesive (PSA)-based material.

14. The display module of claim 1, wherein the adhesive layer comprises polyimide (PI), polyurethane acrylate (PUA), or polyacrylate (PA).

15. The display module of claim 1, further comprising an anisotropic conductive film (ACF) having a black-based color and provided between the first surface of the substrate and the adhesive layer.

16. A display module comprising:
a substrate;
a light emitting diode (LED) provided on the substrate;
an adhesive layer on a surface of the substrate on which the LED is provided; and
an optical film connected to the substrate by the adhesive layer and configured to increase luminous intensity by scattering light emitted by the LED,
wherein the optical film comprises a light scattering layer comprising a light diffusing portion configured to scatter light emitted by the LED.

17. The display module of claim 16, wherein the light scattering layer comprises a first black matrix provided at a first side of the light diffusing portion and a second black matrix provided at a second side of the light diffusing portion.

18. The display module of claim 16, wherein the display module satisfies
$$\frac{1}{{L}_{MFP}} = μ * ρ ,$$
where a ρ is a concentration of a scattering particle of the light diffusing portion, L_{MFP} is a mean-free path length between each scattering particle, and μ is a Mie scattering coefficient.

19. The display module of claim 16, wherein the light diffusing portion comprises:
a resin layer comprising a plurality of protrusions protruding from a surface of the resin layer, and
wherein the plurality of protrusions are provided in a random or quasi-random manner.

20. A display module comprising:
a substrate;
a plurality of light emitting diodes (LEDs) provided on the substrate;
an adhesive layer provided on a first surface of the substrate on which the plurality of LEDs are provided; and
an optical film connected to the substrate by the adhesive layer and configured to increase luminous intensity by scattering light emitted by the plurality of LEDs,
wherein the optical film comprises a light scattering layer comprising:
a plurality of light diffusing portions provided at locations corresponding to the plurality of LEDs and configured to scatter light emitted by respective LEDs of the plurality of LEDs, and
a plurality of black matrices between the plurality of light diffusing portions.
